(19) United States
(12) Patent Application Publication
(10) Pub. No.: US 2009/0098682 A1
(43) Pub. Date: Apr. 16, 2009

(54) Method for Singulating a Group of Semiconductor Packages that Contain a Plastic Molded Body

(75) Inventors: Ludger Mullers, Munchen (DE); Ralf Schmidt, Walkertshofen (DE)

Correspondence Address: LERNER GREENBERG STEMER LLP, P O BOX 2480, HOLLYWOOD, FL, 33022-2480, US

(73) Assignee: CARL BAASEL LASERTECHNIK GMBH & CO. KG, Starnberg (DE)

(21) Appl. No.: 12/251,025

(22) Filed: Oct. 14, 2008

(30) Foreign Application Priority Data
Oct. 13, 2007 (DE) DE102007049160.5

(51) Int. Cl. H01L 21/50

(52) U.S. Cl. 438/113; 257/E21.499

(57) ABSTRACT

A method for singulating a group of semiconductor packages containing a plastic molded body. The singulation of the semiconductor packages is effected along a predetermined separation area, wherein, in the predetermined separation area, a metallic layer extending over at least a partial section of the predetermined separation area has to be cut through in addition to a plastic layer formed of a material of the molded body. The method includes the steps of: making a groove into the predetermined separation area of the semiconductor packages by laser engraving, wherein at least a part of the metallic layer extending in the predetermined singulation area is removed, and subsequent separation of the semiconductor packages by mechanical sawing cut along the predetermined separation area.

### CROSS-REFERENCE TO RELATED APPLICATION

This application claims the priority, under 35 U.S.C. § 119, of German application DE 10 2007 049 160.5, filed Oct. 13, 2007; the prior application is herewith incorporated by reference in its entirety.

### BACKGROUND OF THE INVENTION

### Field of the Invention

The invention relates to a method for singulating semiconductor packages along a predetermined separation area extending between them. In the predetermined separation area, there is a metallic layer extending over at least a partial section of the predetermined separation area, in addition to a plastic layer formed of a material of a molded body.

A semiconductor unit/semiconductor chip/semiconductor package is manufactured using a process divided into a multitude of individual steps. A typical process is disclosed, for example, in international patent disclosure WO 2007/005639 A2 and contains the now described steps.

Typically, first of all, a lead frame produced by punching out from a copper sheet or a copper foil, and a die are joined. The die is positioned in the lead frame and then contacted by fine gold wires, electrically bonding the contacts of the die and those of the lead frame. The lead frame and die are then molded in a package primarily serving for protecting the die against damage and environmental impacts.

To test the dies, now located inside the package, for their operativeness, they are electrically isolated from each other, at least partially, in an isolation cut. The semiconductor chips are still mechanically connected with each other, so that they can be rolled up, for example, in the manner of a tape.

In a last step, plastic molded bodies, i.e. the packages of the individual semiconductor units or semiconductor chips, are singulated. To singulate the packages, they are completely separated from each other, usually by a mechanical sawing cut step. Alternatively, the packages are separated from each other with the help of a laser. After their singulation, the semiconductor units are packaged, so that they are ready for dispatch.

In general, one differentiates between through-hole mounted (Through-Hole Technology—THT) and surface-mounted (Surface-Mounted Devices—SMD) semiconductor packages. A special type of surface-mounted packages is the QFN (Quad Flat No-Lead) package. A QFN package has no contacts protruding over the package edge, as is known from other package types in the form of the typical pins. A QFN package is soldered on the lower surface of the package and is particularly well suited, due to its compactness, for mobile terminals, such as, for example, cellular telephones, PDA's, etc.

In the following, the process step of singulation shall be explained in detail. Laser-machining processes for singulating semiconductor packages have been little successful so far, because the achievable edge quality and process speed are too low. A mechanical sawing process fulfills the requirements concerning process speed, but the lifetime of the saw blades is short. To change the saw blade, the process has to be interrupted from time to time.

The above-mentioned document WO 2007/005639 A2 as well as U.S. patent disclosure No. 2003/0160315 A1 both mention alternatives to the above-described singulation methods. International patent disclosure WO 01/57922 A1 discloses the singulation of the die packages by mechanical sawing cut. U.S. Pat. No. 6,872,599 B1 discloses a variant of the mechanical sawing process. The semiconductor packages are singulated, instead of by a single wide sawing cut, by several narrow sawing cuts carried out parallel to each other.

### SUMMARY OF THE INVENTION

It is accordingly an object of the invention to provide a method for singulating a group of semiconductor packages that contain a plastic molded body which overcomes the above-mentioned disadvantages of the prior art methods of this general type, which is an improved method for singulation of the semiconductor packages.

The semiconductor packages to be singulated are combined in a group and contain a plastic molded body. The singulation of the semiconductor packages is effected along a predetermined separation area, wherein, in the predetermined separation area, a metallic layer extending over at least a partial section of the predetermined separation area has to be cut through in addition to a plastic layer formed of the material of the molded body. The method for singulating the semiconductor packages contains the steps of making a groove into the predetermined singulation area of the semiconductor packages by laser engraving, removing by the laser engraving at least part of the metallic layer extending in the predetermined singulation area, and subsequently complete separation of the semiconductor packages by a mechanical sawing cut along the predetermined separation area.

The technical problems in connection with the singulation of semiconductor packages can be avoided by separating the semiconductor packages using a two-step method. First, a groove is cut into the predetermined separation area between the semiconductor packages properly speaking. The groove is generated by laser engraving. Therefore the material of the semiconductor packages is removed in the area of the groove by the laser beam, the packages being in this way incised or scratched. The metallic layer, present in the predetermined singulation area, is in this way removed, at least partially. The metallic layer is preferably part of the lead frame. Then, the semiconductor packages are completely singulated along the predetermined separation area by a mechanical saw.

The method according to the invention combines the advantages of a laser-based separating method and those of a mechanical separating method. As the laser beam does not separate the semiconductor packages completely from each other, the method is considerably faster that a pure laser process. Furthermore, as compared with a pure sawing process, the lifetime of the saw blade is significantly higher, because the laser engraving operation has already removed part of the metal from the cutting area of the saw blade. Consequently, the latter has contact with less metal when separating the semiconductor packages.

A metallic layer, preferably formed by part of the lead frame, is embedded in the molded body of the semiconductor packages. The metallic layer is spaced less from a large side of the semiconductor package, designated as contact side, than from another large side situated opposite thereto. Therefore, viewed from the contact side, the metallic layer is embedded in the molded body near the surface.

According to an advantageous embodiment of the method, the groove is made/cut into the semiconductor packages from the contact side.

By making a groove into the contact side of the semiconductor packages, a large part of the metallic layer can be removed by laser engraving from the predetermined separation area. Viewed from the contact side, only little molding material of the plastic molded body is present above the metallic layer, whereas the essential part of the plastic molded body extends below the metallic layer. By applying laser engraving to the contact side of the semiconductor packages, a large part of the metallic layer can be removed from the predetermined separation area without having to cut a very deep groove into the semiconductor packages. Therefore, the method works faster and the semiconductor packages remain mechanically connected with each other, which facilitates their further processing.

According to another advantageous embodiment of the method, the lateral width of the groove cut into the die package by laser engraving, maximally corresponds to the cutting width of the mechanical sawing cut, i.e. the lateral width is equal or smaller then the cutting width of the mechanical saw. The lateral width is the extension of the groove in a plane normal to the impact direction of the laser beam. Through this measure, a particularly good edge quality of the cut/singulated semiconductor packages can be achieved. This will become evident from the now described considerations.

With the help of laser engraving, the metal of the lead frame is removed, at least partially, from the cutting area of the mechanical saw. Due to the thermal effect of the laser beam, however, a groove with an unperfect edge may be produced. In particular, the molded body may melt in an undesired way or may be damaged in the area neighboring the contacts of the lead frame. Such damage of parts of the molded body in the area of the groove cut by the laser-engraving operation is due to the greatly differing thermal conductivities of the molded body and the lead frame material and occurs for the now described reasons. As the metal of the lead frame is very strongly heated up by the laser treatment and as its thermal conductivity is high, a heat flow normal to the cutting direction of the laser beam occurs. The heat is transferred by the metal parts to parts of the molded body outside the area of the laser engraving properly speaking. In these boundary areas, the molded body is thermally damaged. An unperfect cutting edge of poor quality is produced. The mechanical sawing cut following the laser engraving removes the unperfect edge and produces a smooth, neat cut in the semiconductor packages. The edge quality of the semiconductor packages singulated in this way achieves a high level. The above-described method achieved a high edge quality of the separated semiconductor packages with, at the same time, a long lifetime of the saw blade.

According to a development of the method, the lateral width of the groove cut by laser engraving into the semiconductor packages is adjusted by carrying out a plurality of laser engraving operations essentially parallel to the separation line. The singulation line extends within the separation area. Through parallel laser engraving operations, the width of the groove can be adjusted in a particularly simple, flexible and effective manner.

In another advantageous embodiment of the method, the depth of the groove cut into the semiconductor packages by laser engraving corresponds at least to the depth by which the lead frame extends into the molded body—viewed in direction of the beam. In particular, the depth of the groove is chosen just large enough for the lead frame being removed almost completely from the groove. The depth of the groove just corresponds in this case—again viewed in direction of the beam—to the maximum depth to which the lead frame extends into the molded body. This maximum depth is given by the distance between the surface of the contact side and the lower edge of the lead frame, so that, in the subsequent mechanical sawing cut along the groove, the saw blade hardly gets into contact with the metal of the lead frame. The lifetime of the saw blade can thus clearly be improved.

According to an advantageous embodiment of the method, the depth of the groove made into the semiconductor packages by laser engraving is adjusted by the number of laser engraving operations carried out substantially along the same cutting line. In other words, several laser engraving operations are carried out along one and the same line in the semiconductor packages, the positions of the individual laser engraving operations only differing by inaccuracies caused by the apparatus. When several laser engraving operations are carried out along the same cutting line, it is possible in a particularly simple, flexible and effective manner to adjust the depth of the groove made by laser engraving.

According to a development of the method, the laser engraving is affected by laser pulses having in particular a pulse length between 0.5 μs and 5 μs. Such laser pulses are preferably generated by a Q-switched solid-state laser. Using laser pulses, a high material-removal rate with, at the same time, a low heat supply to the work piece is achieved. Therefore by using a laser beam one always understands both a continuous and a pulsed laser beam.

The semiconductor packages are preferably QFN packages. Such semiconductor packages are particularly compact and have a high metal share. Due to the high metal share, a very high wear will occur on the saw blades when mechanically singulating QFN packages. Therefore, the wear-reducing method according to the invention is particularly advantageous for QFN packages.

Other features which are considered as characteristic for the invention are set forth in the appended claims.

Although the invention is illustrated and described herein as embodied in a method for singulating a group of semiconductor packages that contain a plastic molded body, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF SEVERAL VIEWS OF THE DRAWING

FIG. 1 is a diagrammatic, perspective view of a semiconductor package according to the invention;

FIG. 2 is a diagrammatic, top view of a tape with a group of semiconductor packages;

FIG. 3 is a detail view in an area between two adjacent semiconductor packages; and

FIGS. 4 and 5 are diagrammatic, cross-sectional views of the semiconductor package.

### DETAILED DESCRIPTION OF THE INVENTION

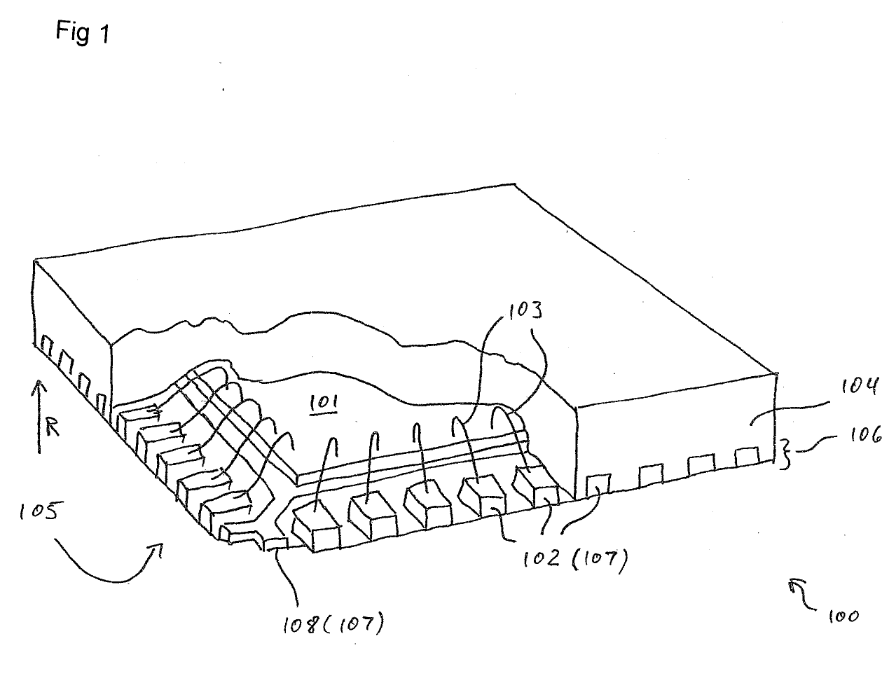

Referring now to the figures of the drawing in detail and first, particularly, to FIG. 1 thereof, there is shown a semiconductor package 100 of a semiconductor chip or a semiconductor unit. The semiconductor package 100 shown as an example is a QFN package. A die 101 is connected with the electrical contacts 102 of the semiconductor package 100 by fine gold wires 103. The electrical contacts 102 are molded together with the die 101 and the gold wires 103 in a molded body 104. The material of the molded body 104 can be, for example, a thermosetting polymer or an epoxy resin. The electrical contacts 102 are embedded in a contact side 105, which in FIG. 1 corresponds to a lower surface of the die package 100. The contacts 102 and another holding structure 108 for the die 101, also embedded in the molded body 104, are part of a lead frame 107 embedded in the molded body 104. The parts constituting the lead frame 107, such as, for example, the contacts 102 and the holding structure 108, form a metallic layer 106 inside the molded body 104.

To singulate several semiconductor packages 100, preferably combined in a group, these are preferably treated in a first step by a laser beam from a direction R, and in a second step, the semiconductor packages 100 are separated by a mechanical sawing cut.

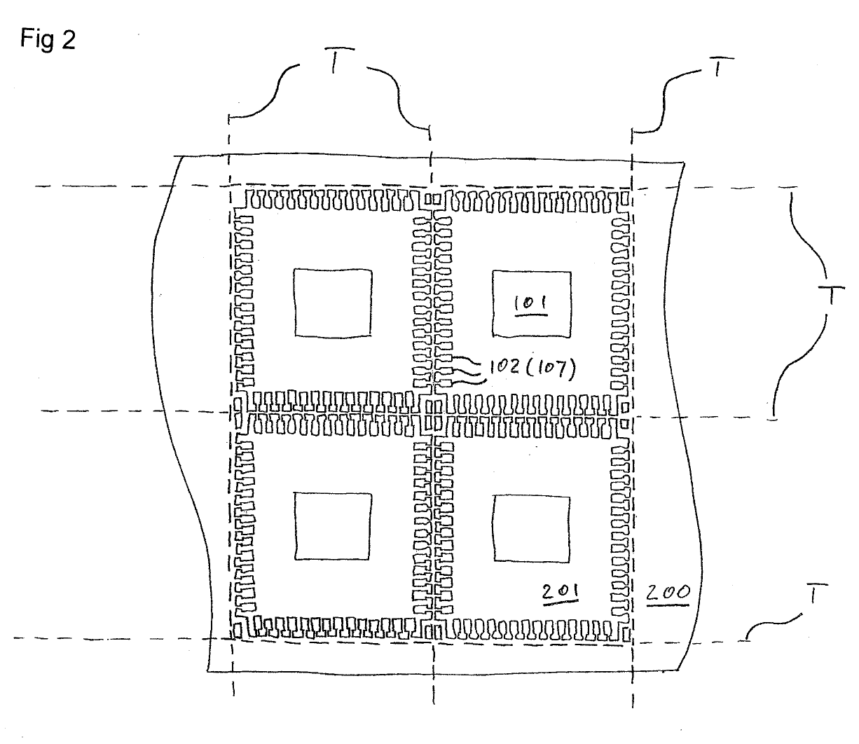

For easier mass processing, the semiconductor packages 100 are arranged on a carrier tape 200, as shown in FIG. 2. The carrier tape 200 can be, for example, a copper foil, from which the respective lead frame 107 of the individual semiconductor packages 100 has been punched out before. During the punching out process, an opening 201 is formed in the carrier tape 200. The punching-out process creates individual contacts 102, which are part of the lead frame 107 and are mechanically held together by further parts of the lead frame 107. The lead frame 107 offers a receptacle for the die 101, whose position is indicated in FIG. 2. The individual semiconductor packages 100 are situated in one or more groups on the carrier tape 200. In FIG. 2, for the sake of clarity, only 4 semiconductor packages 100 form a group, however, such a group may consist of a considerably higher number of semiconductor packages 100, for example 64 or 100 packages. Furthermore, several groups can be arranged one beside the other in longitudinal and in cross direction of the tape 200.

The individual semiconductor packages are subjected to various process steps, before they can finally be packaged, ready for dispatch. After the individual semiconductor chips, more precisely, their dies 101, have been tested for operativeness and correspondingly operative semiconductor units have been marked as such, the semiconductor packages 100 are singulated. For the purpose of singulation of the semiconductor packages 100, cuts are made in the packages 100 and, if necessary, also in the carrier tape 200, along the separation lines T extending between the semiconductor packages 100. For the sake of clarity, only a few separation lines T necessary for singulating the semiconductor packages 100 are indicated in FIG. 2.

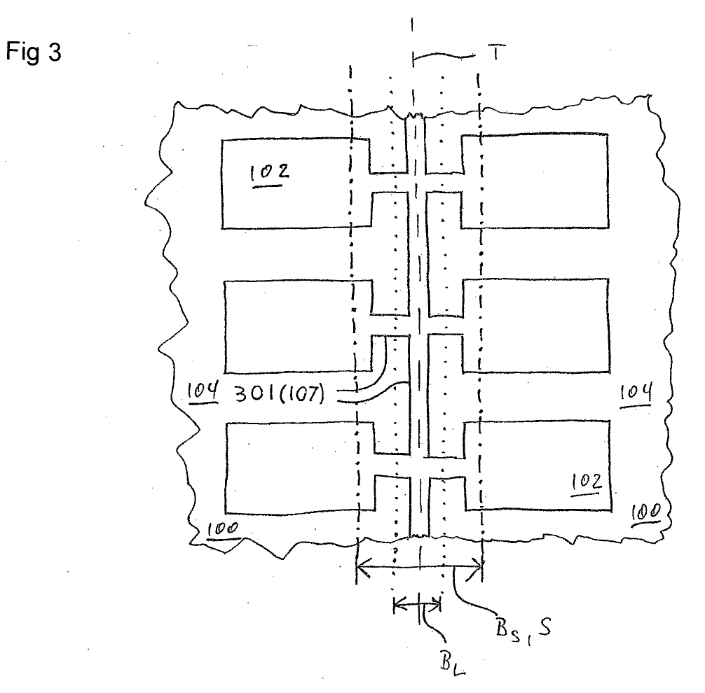

FIG. 3 is a detail view of two semiconductor packages 100 adjacent to each other. The semiconductor packages 100 to be separated from each other along the separation line T are connected with each other through webs 301, which connect the individual contacts 102 of the respective semiconductor packages 100 with each other, as well as through their molded body 104. The lead frame 107 of the semiconductor packages 100 is substantially formed by the webs 301. The separation line T is surrounded by a predetermined separation area S. The predetermined separation area S extends between the semiconductor packages 100 properly speaking, but can catch their edge. The semiconductor packages 100 are singulated within or along this predetermined singulation area S.

To singulate the semiconductor packages 100, a groove of width B_{L} is made, in a first step, into the semiconductor packages 100 by one or more laser engraving operations. The laser engraving operations are carried out substantially parallel to the separation line T. To adjust a width B_{L} of the groove made by laser engraving, several laser engraving operations are carried out substantially parallel to each other. The groove made by the laser engraving operations has a width B_{L} substantially corresponding to the width of that web 301 of the lead frame 107 which connects the webs 301 branching off to the individual contacts 102 with each other along the separation line T. The width of one laser engraving operation lies typically in the range of 50 μm.

After the laser engraving has been affected, the semiconductor packages 100 will be completely separated from each other, in a second process step, by a mechanical saw. For this purpose, a cut is made in the semiconductor packages 100 in the predetermined separation area S, substantially along the separation line T. The mechanical sawing cut is made in like manner in the two adjoining semiconductor packages 100.

In the exemplary embodiment shown in FIG. 3, a width Bs of the mechanical sawing cut and the width of the predetermined separation area S are identical. This is not necessarily the case. The mechanical sawing cut should lie inside the predetermined singulation area, but its width can also be smaller, if necessary.

The predetermined singulation area S is chosen such that the semiconductor packages 100 are separated from each other. Therefore, the width of the predetermined singulation area S has to be at least such that the webs 301 mechanically connecting the contacts 102 with each other are separated. Usually, however, the width of the predetermined singulation area S is chosen such that the webs 301 of the lead frame are completely removed. To achieve a smooth terminating edge on the semiconductor packages 100, the width of the predetermined separation area S can also be chosen so large that a partial area of the contacts 102 is caught by the mechanical sawing cut lying inside the predetermined separation area S.

The width B_{S} of the mechanical sawing cut, which is approximately 300 μm, is larger, but at least as large as the width B_{L} of the groove produced by one or more laser engraving operation(s). Any burr or notches remaining after the laser treatment in the area of the edge of the semiconductor packages 100, which would lead to a poorer quality of this edge, can be removed by the mechanical sawing cut. In this way, a smooth edge of cut can be generated on the singulated semiconductor packages 100.

The laser engraving carried out in the first process step as well as the mechanical sawing cut carried out in the second process step can be effected in the semiconductor packages 100 in particular from the contact side 105. Therefore, the contact side 105 of the semiconductor packages 100 is treated in the predetermined separation area S by a laser beam from the direction R in such a way that in the predetermined separation area S, material of the die packages 100 is removed. This process removes both metal and plastic from the predetermined separation area S, thus creating a recess or groove in the predetermined separation area S.

Laser engraving can be affected in particular with a Q-switched solid-state laser having a pulse length between 0.5 μs and 5 μs, i.e. by the term “laser beam”, one always also understands a sequence of laser pulses. The subsequent mechanical sawing cut can be carried out in particular with a dicing saw.

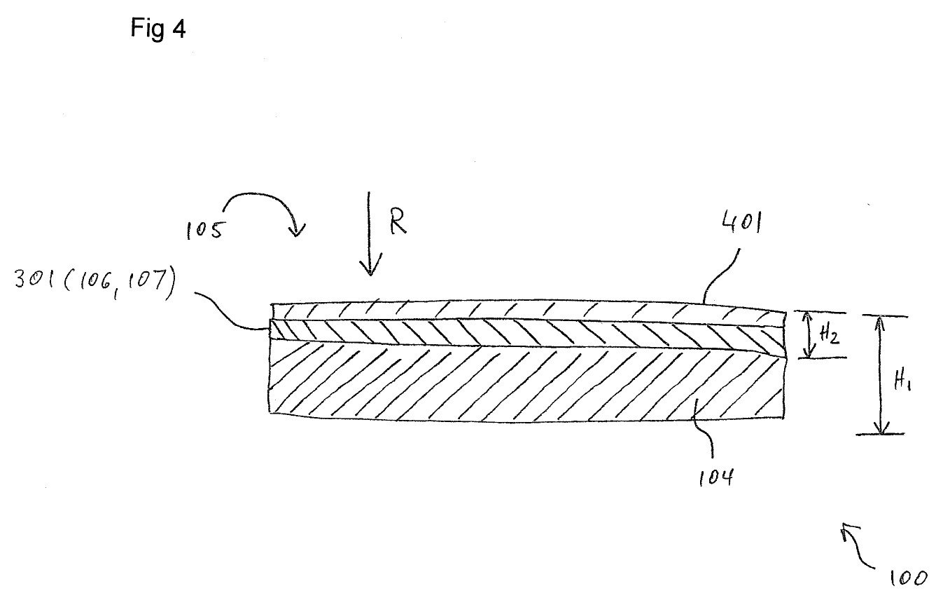

FIG. 4 is a cross-sectional view of the semiconductor package 100 along the separation line T shown in FIG. 3. The separation package 100 has a total height H₁, the lead frame 107 extending, viewed from the contact side 105, up to a depth H₂. In the area of the separation line T, the lead frame 107 includes a continuous web 301 (see FIG. 3). The contact side 105 is covered with a covering layer 401. Below the lead frame 107, viewed from the contact side 105, the molded body 104 of the semiconductor package 100 extends.

To singulate, for example, two semiconductor packages 100, a laser engraving extending up to the depth H₂ can be produced in the semiconductor packages 100 from the contact side 105. For this purpose, a laser beam is directed from the direction R onto the contact side 105 of the semiconductor packages 100. The laser parameters for generating the groove are adjusted such that the metal of the lead frame 107, i.e. in particular the web 301, can be removed almost completely from the generated groove, i.e. the generated groove extends just up to the depth H₂. The covering layer 401 present on the contact side 105 of the semiconductor package 100 is also removed by the engraving operation.

The depth of the groove, i.e. the depth of material removal generated by the laser pulses, can be adjusted in particular by carrying out several laser engraving operations one after another along the same line. The laser beam is passed several times over the semiconductor package 100 along the same path, except for inevitable inaccuracies caused by the apparatus. To generate the groove, the laser engraving can in particular be effected in such a way that on the one hand, as described in connection with FIG. 3, several laser engraving operations are carried out parallel to each other, and, on the other hand, as described in connection with FIG. 4, several laser engraving operations are carried out along the same line for adjusting the engraving depth.

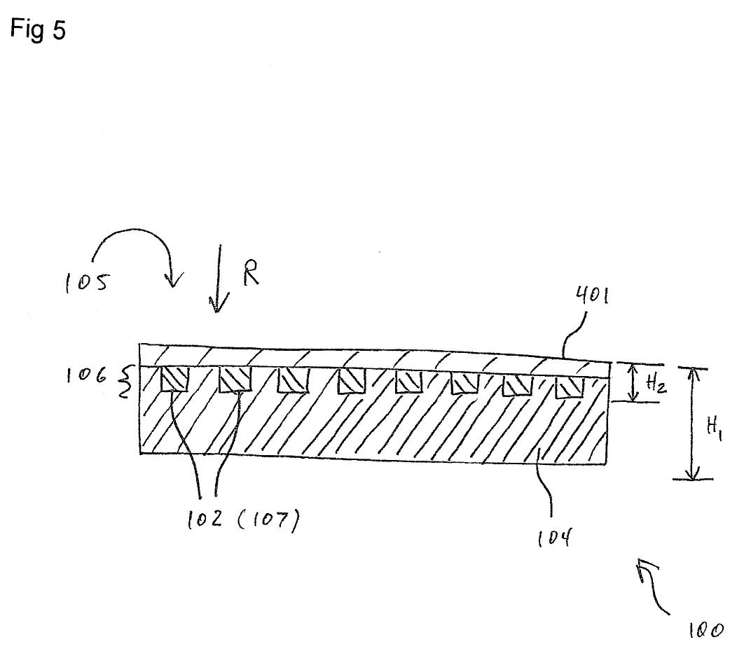

FIG. 5 is another cross-sectional view of the semiconductor package 100 along a boundary line of the predetermined singulation area S. The individual contacts 102 are embedded in the molded body 104 of the semiconductor package 100. The contact side 105 is provided with the covering layer 401. As mentioned before, after the laser engraving operation, the semiconductor packages 100 are singulated from each other through a mechanical sawing cut having the width Bs. After the largest part of the metal has been removed from the predetermined separation area S already through the groove cut by the laser, a neat edge is cut into the semiconductor packages 100 by the mechanical sawing cut.

1. A method for singulating a group of semiconductor packages containing a plastic molded body, by separation along a predetermined separation area, wherein, in the predetermined separation area, a metallic layer extending over at least a partial section of the predetermined separation area has to be cut through in addition to a plastic layer containing a material of the plastic molded body, which comprises steps of:
making a groove in the predetermined separation area of the semiconductor packages by laser engraving, at least a part of the metallic layer extending in the predetermined separation area being removed; and
subsequently performing a complete separation of the semiconductor packages by a mechanical sawing cut performed along the predetermined separation area.

2. The method according to claim 1, which further comprises making the groove into a contact side of the semiconductor packages, the contact side being that large side of a die package from which the metallic layer embedded in the molded body is spaced less than from another large side situated opposite thereto.

3. The method according to claim 1, which further comprises forming a lateral width of the groove made by the laser engraving to be equal or smaller then a cutting width of the mechanical sawing cut.

4. The method according to claim 3, which further comprises making the groove by means of a number of laser engraving operations, carried out substantially parallel to a singulation line lying in the predetermined separation area.

5. The method according to claim 4, which further comprises adjusting the lateral width of the groove by a number of laser engraving operations.

6. The method according to claim 1, which further comprises forming a depth of the groove made by the laser engraving to correspond at least to a depth by which a lead frame extends into the plastic molded body—viewed in direction of a laser beam.

7. The method according to claim 1, which further comprises adjusting a depth of the groove made by the laser engraving by a number of laser engraving operations carried out substantially along a same cutting line.

8. The method according to claim 1, which further comprises performing the laser engraving with laser pulses.

9. The method according to claim 8, which further comprises setting the laser pulses with a pulse length of 0.5 μs to 5 μs.

10. The method according to claim 1, which further comprises using QFN semiconductor packages as the semiconductor packages.

11. The method according to claim 1, which further comprises performing the laser engraving with a Q-switched solid-state laser.
